(19) United States
(12) Patent Application Publication
(10) Pub. No.: US 2025/0374640 A1
(43) Pub. Date: Dec. 4, 2025

(54) SEMICONDUCTOR DEVICE AND METHOD FOR FABRICATING THE SAME

(71) Applicant: SK hynix Inc., Gyeonggi-do (KR)

(72) Inventor: Sung Hwan HWANG, Gyeonggi-do (KR)

(21) Appl. No.: 19/004,482

(22) Filed: Dec. 30, 2024

(30) Foreign Application Priority Data
May 30, 2024 (KR) 10-2024-0070967

(51) Int. Cl. H10D 64/27; H10B 12/00

(52) U.S. Cl. CPC H10D 64/513; H10B 12/315; H10B 12/482; H10B 12/488

(57) ABSTRACT

A semiconductor device includes an active region disposed in a substrate; a first node and a second node defined in the active region; and a buried electrode. The buried electrode includes a linear portion disposed between the first node and the second node to be through the active region, and an extended portion protruding from the linear portion to partially cover side walls of the second node.

### CROSS-REFERENCE TO RELATED APPLICATIONS

The present application claims priority under 35 U.S.C 119(a) to Korean Patent Application No. 10-2024-0070967, filed on May 30, 2024, which is incorporated herein by reference in its entirety.

### BACKGROUND

### 1. Field

Various embodiments of the present disclosure relate to a semiconductor device, and more particularly, to a semiconductor device including a buried gate structure, and a method for fabricating the same.

### 2. Description of the Related Art

Metal gate electrodes are applied to achieve high performance of transistors. Particularly, it is required to control a threshold voltage for a high-performance operation in a buried gate-type transistor. Further, gate-induced drain leakage (GIDL) characteristics have a significant influence on the performance of the buried gate-type transistors.

### SUMMARY

Embodiments of the present disclosure are directed to a semiconductor device including a buried gate structure with improved reliability, and a method for fabricating the semiconductor device.

In accordance with an embodiment of the present disclosure, a semiconductor device may include an active region disposed in a substrate; a first node and a second node defined in the active region; and a buried electrode including: a linear portion disposed between the first node and the second node to be through the active region; and an extended portion protruding from the linear portion to partially cover side walls of the second node.

In accordance with another embodiment of the present disclosure, a semiconductor device may include an active region including a first node and a second node including a plurality of side wall facets; a trench including a linear portion defined between the first node and the second node, and a plurality of non-linear portions exposing the side wall facets of the second node; and a gate electrode filling the linear portion and the non-linear portions of the trench and covering portions of the side wall facets.

In accordance with another embodiment of the present disclosure, a semiconductor device may include a first active node including a plurality of first side wall facets; a second active node including a plurality of second side wall facets, the first active node and the second active node being defined in a substrate; a bit line disposed over the substrate and coupled to the first active node; a data storage element disposed over the substrate and coupled to the second active node; and a gate electrode buried between the first active node and the second active node, wherein the gate electrode includes: a first segment facing one first side wall facet among the plurality of first side wall facets; and second segments extending from the first segment and covering at least three second side wall facets among the plurality of second side wall facets.

In accordance with another embodiment of the present disclosure, a semiconductor device may include a pillar-shaped node having a plurality of first side wall facets; a vertical fin having a plurality of second side wall facets; and a conductive structure buried between the pillar-shaped node and the vertical fin, wherein the conductive structure includes a first segment facing one first side wall facet among the first side wall facets; and second segments extending from the first segment and covering at least three second side wall facets among the second side wall facets.

In accordance with another embodiment of the present disclosure, a semiconductor device may include active regions that include a buried word line extending in a first direction, a bit line extending in a second direction intersecting with the first direction, a first node of a pillar shape coupled to the bit line and disposed at an intersection between the buried word line and the bit line, and a second node of a vertical fin structure facing the first node and having multi-sided facets; data storage elements respectively coupled to the second nodes of the active regions; a linear first gate dielectric layer formed between the first nodes and the buried word line; and a non-linear second gate dielectric layer formed between the second nodes and the buried word line, wherein the first nodes, the buried word line, and the second nodes may be disposed in one direction, and one buried word line may be disposed in each of the active regions, and the buried word line may include an extended buried electrode covering some of the multi-sided facets of the second node.

### BRIEF DESCRIPTION OF THE DRAWINGS

FIG. 1A is a plan view illustrating a semiconductor device in accordance with an embodiment of the present disclosure.

FIG. 1B is a cross-sectional view taken along a line A-A′ shown in FIG. 1A.

FIG. 1C is a cross-sectional view taken along a line B-B′ shown in FIG. 1A.

FIG. 1D is a detailed plan view illustrating a trench and an active region shown in FIGS. 1A and 1B.

FIG. 1E is a detailed plan view illustrating a gate electrode shown in FIGS. 1A and 1B.

FIG. 1F illustrates an example of a data storage element shown in FIGS. 1A and 1B.

FIG. 2A is a plan view illustrating a semiconductor device in accordance with an embodiment of the present disclosure.

FIG. 2B is a cross-sectional view taken along a line A1-A1′ shown in FIG. 2A.

FIG. 2C is a plan view illustrating a trench and an active region shown in FIGS. 2A and 2B.

FIGS. 3A to 7B illustrate a method for fabricating a semiconductor device in accordance with an embodiment of the present disclosure.

FIGS. 8 to 12 are plan views illustrating semiconductor devices in accordance with other embodiments of the present disclosure.

FIG. 13 is a schematic plan view illustrating a semiconductor device according to a comparative example.

FIGS. 14 and 15 illustrate semiconductor devices in accordance with other embodiments of the present disclosure.

### DETAILED DESCRIPTION

Various embodiments of the present disclosure will be described below in more detail with reference to the accompanying drawings. The embodiments of the present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure. The drawings are not necessarily to scale and in some instances, proportions may have been exaggerated in order to clearly illustrate features of the embodiments. When a first layer is referred to as being ‘on’ a second layer or ‘on’ a substrate, it not only may refer to a case where the first layer is formed directly on the second layer or the substrate but also a case where a third layer exists between the first layer and the second layer or the substrate.

In the following embodiments of the present disclosure, a buried gate structure may be disposed in a trench of a substrate. The buried gate structure may include a stack of a gate dielectric layer, a gate electrode, and a capping layer. The gate dielectric layer may cover the surface of the trench, and the gate electrode may fill a portion of the trench over the gate dielectric layer, and the capping layer may fill the remaining portion of the trench over the gate electrode. Therefore, the gate electrode may be referred to as a ‘buried gate electrode’.

The gate electrode may include a single gate or a dual gate. A single gate may refer to a gate that is formed of polysilicon alone or a metal-based material alone. The single gate may include a polysilicon single gate or a metal single gate. A dual gate may refer to a bilayer stack of different gate materials. The dual gate may include a same metal dual gate which is formed of a stack of the same metal, a heterogeneous metal dual gate which is formed of a stack of different metals, or a heterogeneous material dual gate which is formed of a stack of a metal and polysilicon.

The gate electrode may include a barrier layer and a low resistance material. The barrier layer may serve to block the dopants diffusing from the low resistance material or to prevent the diffusion and reaction between different materials. The low resistance material may serve to decrease the sheet resistance of the gate electrode.

The gate electrode may include a material whose work function is engineered. Work function engineering may refer to a material or method that may adjust the work function to have a decreased work function (i.e., a low work function) or an increased work function (i.e., a high work function).

Row hammering may refer to a threshold voltage degradation phenomenon that is caused by a passing gate and a neighboring gate. The passing gate effect and the neighbor gate effect are phenomena that when a word line is enabled based on an active command, the threshold voltage of a cell transistor of a neighboring word line that is turned off is decreased. The passing gate effect is a phenomenon in which the threshold voltage of a cell transistor of a word line in another neighboring active region is decreased when the word line is enabled. The neighbor gate effect is a phenomenon in which the threshold voltage of the cell transistor of the word line in the same active region is decreased when the word line is enabled.

The threshold voltage that is decreased due to the row hammering may increase the amount of off leakage, which may cause a failure of a cell.

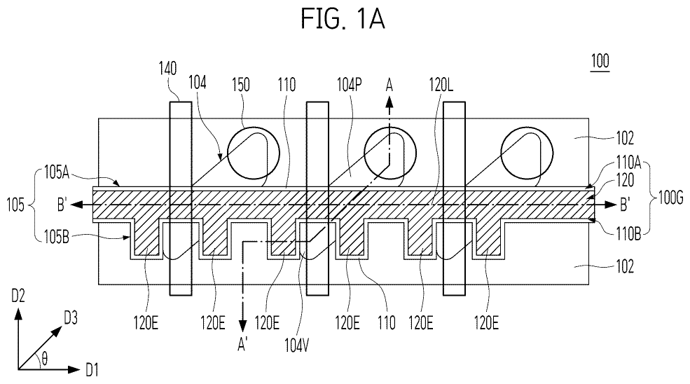

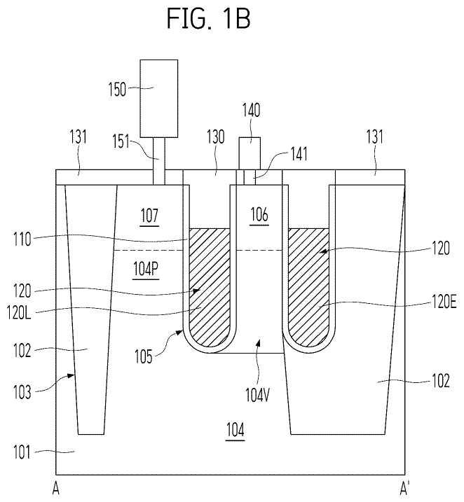

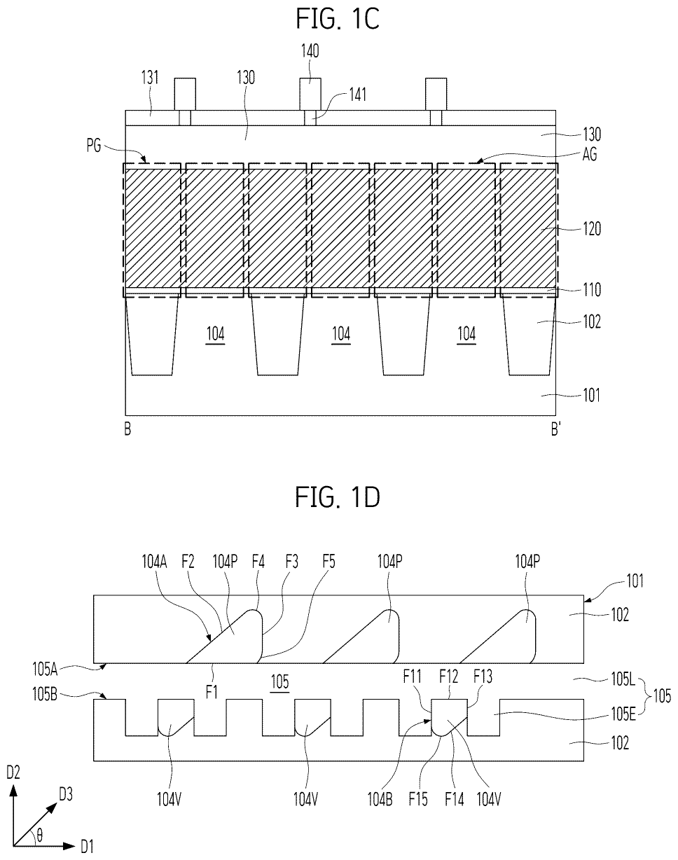

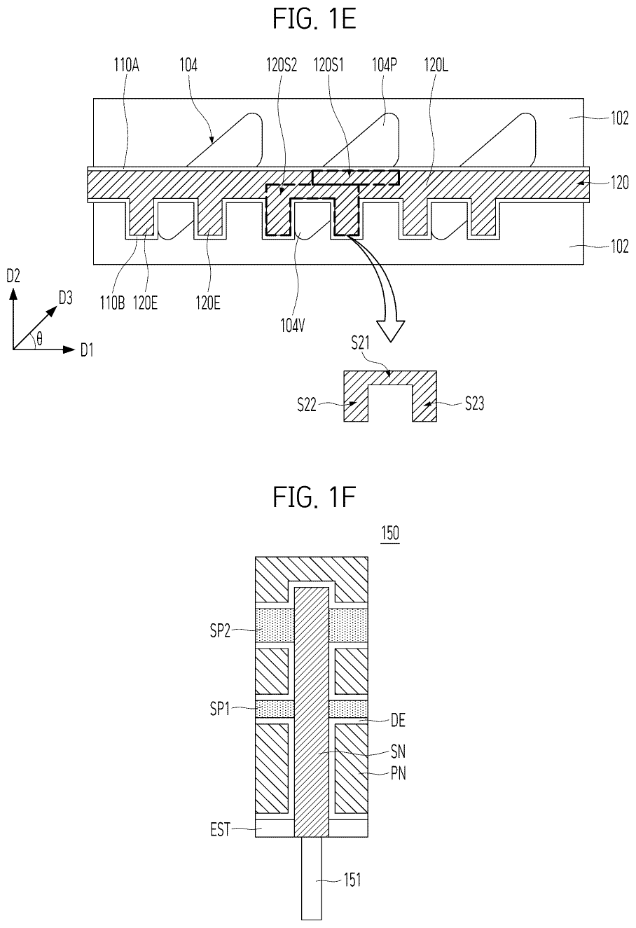

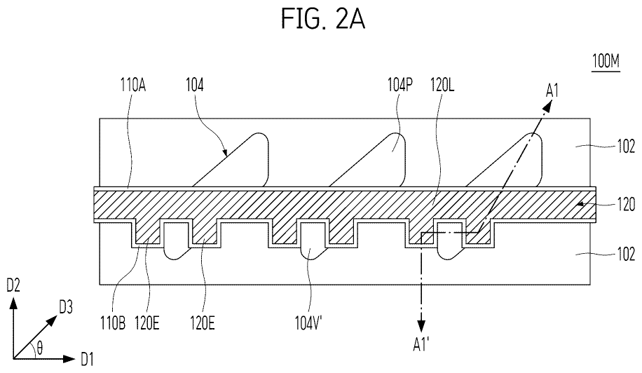

FIG. 1A is a plan view illustrating a semiconductor device in accordance with an embodiment of the present disclosure. FIG. 1B is a cross-sectional view taken along a line A-A′ shown in FIG. 1A. FIG. 1C is a cross-sectional view taken along a line B-B′ shown in FIG. 1A. FIG. 1D is a detailed plan view illustrating a trench and an active region shown in FIGS. 1A and 1B. FIG. 1E is a detailed plan view illustrating a gate electrode shown in FIGS. 1A and 1B. FIG. 1F illustrates an example of a data storage element 150 shown in FIGS. 1A and 1B.

Referring to FIGS. 1A to 1F, a semiconductor device 100 may include a substrate 101, a plurality of buried gate structures 100G, a plurality of bit lines 140, and a plurality of data storage elements 150. The semiconductor device 100 may include a plurality of memory cells. For example, the semiconductor device 100 may be a portion of a Dynamic Random Access Memory (DRAM). Each memory cell may include one buried gate structure 100G, one bit line 140, and one data storage element 150. The buried gate structures 100G may extend in a first direction D1, and the bit lines 140 may extend in a second direction D2. The first direction D1 and the second direction D2 may be orthogonal to each other.

The buried gate structure 100G may include a trench 105 formed in the substrate 101, a gate dielectric layer 110 covering the bottom surface and side walls of the trench 105, a gate electrode 120 filling a portion of the trench 105 over the gate dielectric layer 110, and a capping layer 130 over the gate electrode 120. The buried gate structure 100G may be referred to as a buried word line structure, and the gate electrode 120 may be referred to as a buried word line. According to another embodiment of the present disclosure, the gate electrode 120 may be referred to as a buried gate or a buried gate electrode.

The substrate 101 may be a material appropriate for semiconductor processing. The substrate 101 may include a semiconductor substrate. The substrate 101 may be formed of a material containing silicon. The substrate 101 may include silicon, single crystalline silicon, polysilicon, amorphous silicon, silicon germanium, single crystalline silicon germanium, polycrystalline silicon germanium, carbon-doped silicon, a combination thereof, or a multi-layer thereof. The substrate 101 may also include other semiconductor materials, such as germanium. The substrate 101 may also include a III/V-group semiconductor substrate, for example, a compound semiconductor substrate, such as gallium arsenide (GaAs). The substrate 101 may also include a Silicon-On-Insulator (SOI) substrate. An isolation layer 102 and a plurality of active regions 104 may be formed in the substrate 101. A plurality of active regions 104 may be defined by the isolation layer 102. The isolation layer 102 may be a shallow trench isolation (STI) region which is formed by etching the trench. The isolation layer 102 may be formed by filling a shallow trench, for example, an isolation trench 103, with a dielectric material. The isolation layer 102 may include silicon oxide, silicon nitride, or a combination thereof.

The trench 105 may be formed in the substrate 101. From the perspective of the plan view of FIG. 1A, the trench 105 may have a line shape extending in the first direction D1. The trench 105 may have a line shape crossing the active regions 104 and the isolation layer 102. The trench 105 may have a shallower depth than the isolation trench 103. According to another embodiment of the present disclosure, the trench 105 may be a space in which the buried gate structure 100G is formed, and the trench 105 may be referred to as a ‘gate trench’. The trench 105 may include a first side wall 105A and a second side wall 105B. The first side wall 105A of the trench 105 may have a linear shape extending in the first direction D1, and the second side wall 105B of the trench 105 may have a non-linear shape extending in the first direction D1. Here, the non-linear shape of the second side wall 105B may be referred to as a wave shape. The first side wall 105A of the trench 105 may be referred to as a linear portion, and the second side wall 105B may be referred to as a non-linear portion.

The active regions 104 may include strips and may be arranged in the form of an array. The array of the active regions 104 may include a row array. The row array of the active regions 104 may include active regions 104 that are arranged in the first direction D1. The longitudinal direction of the active regions 104, i.e., a third direction D3, may be non-orthogonal to the first direction D1 and the second direction D2 to form an intersection angle (θ). The intersection angle (θ) between the first direction D1 and the third direction D3 of the active region 104 may range from approximately 10° to 80°, but the concept and spirit of the present embodiment may not be limited thereto. The range of the intersection angle (θ) may be affected by such parameters as the area of the active region 104, the line width of the bit line 140, and the line width of the buried gate structure 100G. From the perspective of a top view, the cross-section of each active region 104 may be a parallelogram, for example, a parallelogram with rounded edges. According to another embodiment of the present disclosure, the active regions 104 may further include a column array, and the column array may include active regions 104 that are arranged in the second direction D2.

The active regions 104 may be arranged in a unidirection of the third direction D3.

Referring back to FIGS. 1A, 1B, and 1D, each of the trenches 105 may divide each of the active regions 104 arranged in the first direction D1 into a first node 104P and a second node 104V. The first and second nodes 104P and 104V may be referred to as first and second contact regions, respectively. The first node 104P and the second node 104V may be asymmetrical to each other in the third direction D3. The size (or volume) of the first node 104P may be greater than the size (or volume) of the second node 104V. The length of the first node 104P in the third direction D3 may be greater than the length of the second node 104V in the third direction D3. According to another embodiment of the present disclosure, the size (or volume) of the first node 104P and the size (or volume) of the second node 104V may be the same. The first node 104P and the second node 104V may be referred to as active nodes. The first node 104P may be a capacitor contact node, and the second node 104V may be a bit line contact node. The first node 104P may be a pillar-type node, and the second node 104V may be a vertical fin.

Each of the first node 104P and the second node 104V may include a plurality of side wall facets. The side wall facets may be referred to as side walls. Each of the first node 104P and the second node 104V may be referred to as a multi-side wall facet active node. The first and second nodes 104P and 104V may include a semiconductor material. The first and second nodes 104P and 104V may be formed of a material containing silicon. The first and second nodes 104P and 104V may include silicon, single crystalline silicon, polysilicon, amorphous silicon, silicon germanium, single crystalline silicon germanium, polycrystalline silicon germanium, carbon-doped silicon, a combination thereof, or a multi-layer thereof.

The first node 104P may be considered to be included in a first multi-sided region 104A. The first multi-sided region 104A may be a four-sided region including four side wall facets. The first node 104P may include a plurality of side wall facets F1, F2, F3, F4 and F5. The side wall facets F1, F2, F3, F4 and F5 of the first node 104P may include a gate-side facet F1 and isolation layer-side facets F2, F3, F4 and F5. The gate-side facet F1 may directly contact the gate dielectric layer 110 and may be adjacent to the gate electrode 120. The isolation layer-side facets F2, F3, F4 and F5 may directly contact the isolation layer 102. In another embodiment, the side wall facets F1, F2, F3, F4 and F5 of the first node 104P may include linear side wall facets F1, F2 and F3 and non-linear side wall facets F4 and F5. The linear side wall facets F1, F2 and F3 may include a flat surface, and the non-linear side wall facets F4 and F5 may include a rounded surface. The linear side wall facet F1 of the first node 104P may be a gate-side facet, and the linear side wall facets F2 and F3 and the non-linear side wall facets F4 and F5 may be isolation layer-side facets.

The second node 104V may be considered to be included in a second multi-sided region 104B. The second multi-sided region 104B may be a four-sided region including four side wall facets. The second node 104V may include a plurality of side wall facets F11, F12, F13, F14 and F15. The side wall facets F11, F12, F13, F14 and F15 of the second node 104V may include gate-side facets F11, F12 and F13 and isolation layer-side facets F14 and F15. The gate-side facets F11, F12 and F13 may directly contact the gate dielectric layer 110 and may be adjacent to the gate electrode 120. The isolation layer-side facets F14 and F15 may directly contact the isolation layer 102. In another embodiment, the side wall facets F11, F12, F13, F14 and F15 of the second node 104V may include linear side wall facets F11, F12, F13 and F14 and non-linear side wall facets F15. The linear side wall facets F11, F12, F13 and F14 may include a flat surface, and the non-linear side wall facets F15 may include rounded surfaces. The linear side wall facets F11, F12 and F13 of the second node 104V may be gate-side facets, and the linear side wall facet F14 and the non-linear side wall facets F15 may be isolation layer-side facets.

Since the first node 104P and the second node 104V have different sizes, an asymmetric node structure may be formed. The first and second multi-sided regions 104A and 104B may be referred to as first and second multi-sided facets.

The first side wall 105A of the trench 105 may be provided by the side wall facets F1 of the first nodes 104P and the isolation layer 102. The second side wall 105B of the trench 105 may be provided by the side wall facets F11, F12 and F13 of the second nodes 104V and the isolation layer 102.

The trench 105 may include a linear trench portion 105L and a plurality of extended trench portions 105E extending from the linear trench portion 105L. The linear trench portion 105L of the trench 105 may extend in the first direction D1, and the extended trench portions 105E of the trench 105 may extend in the second direction D2. The linear trench portion 105L of the trench 105 may expose the side wall facet F1 of the first node 104P and the side wall facet F12 of the second node 104V. The extended trench portions 105E of the trench 105 may expose the side wall facets F11 and F13 of the second node 104V. The linear trench portion 105L and the extended trench portions 105E of the trench 105 may expose the side wall facets F11, F12 and F13 of the second node 104V. The linear trench portion 105L may cross the isolation layer 102 in the first direction D1. The extended trench portions 105E may extend into the isolation layer 102 in the second direction D2.

As described above, one side wall facet F1 among the side wall facets F1 to F5 of the first node 104P may be exposed by the linear trench portion 105L of the trench 105, and three side wall facets F11, F12 and F13 among the side wall facets F11 to F15 of the second node 104V may be exposed. The surface area of the side wall facet F1 of the first node 104P may be equal to the total surface area of the side wall facets F11, F12 and F13 of the second node 104V. According to another embodiment of the present disclosure, the total surface area of the side wall facets F11, F12 and F13 of the second node 104V may be greater than the surface area of the side wall facet F1 of the first node 104P.

The second node 104V may be referred to as a vertical fin, and the side wall facets F11, F12 and F13 of the second node 104V may be referred to as a multi-facet fin.

The gate dielectric layer 110 may be formed on the side walls and the bottom surface of the trench 105. The gate dielectric layer 110 may include a linear portion 110A and a non-linear portion 110B. The linear portion 110A of the gate dielectric layer 110 may be formed on the first side wall 105A of the trench 105. The non-linear portion 110B of the gate dielectric layer 110 may be formed on the second side wall 105B of the trench 105. The linear portion 110A of the gate dielectric layer 110 may cover the side wall facet F1 of the first node 104P. The non-linear portion 110B of the gate dielectric layer 110 may cover the side wall facets F11, F12 and F13 of the second node 104V. The linear portion 110A of the gate dielectric layer 110 may be referred to as a linear gate dielectric layer, and the non-linear portion 110B of the gate dielectric layer 110 may be referred to as a non-linear gate dielectric layer.

Referring back to FIGS. 1A, 1B, 1D, and 1E, the gate electrode 120 may include a linear buried electrode (i.e., a linear portion of the gate electrode 120) 120L and a plurality of extended buried electrodes (i.e., extended portions of the gate electrode 120) 120E. The linear buried electrode 120L may fill a portion of the linear trench portion 105L over the gate dielectric layer 110, and the extended buried electrodes 120E may fill a portion of the extended trench portions 105E over the gate dielectric layer 110. Based on one second node 104V, the extended buried electrodes 120E may have a double structure, and the extended buried electrodes 120E of the double structure may be symmetrical to each other.

Referring back to FIG. 1C, the gate electrode 120 may include active gates AG and passing gates PG. The active gates AG may be the portions disposed over the active region 104, and the passing gates PG may be the portions disposed over the isolation layer 102. The linear buried electrode 120L and the extended buried electrodes 120E may include the active gates AG and the passing gates PG. The heights of the active gates AG and the heights of the passing gates PG may be the same.

In another embodiment, referring back to FIG. 1E, the gate electrode 120 may have a comb-shaped structure including a plurality of segments 120S1 and 120S2. For example, the gate electrode 120 may include a first segment 120S1 and a second segment 120S2. The first segment 120S1 may face the first node 104P, and the second segment 120S2 may face the second node 104V. The second segment 120S2 of the gate electrode 120 may have a bent shape of a n-shape that surrounds a portion of the second node 104V. The second segment 120S2 may include three sub-segments S21, S22 and S23. The sub-segment S21 may correspond to the body of the comb-shaped structure, and the sub-segments S22 and S23 may correspond to the teeth of the comb-shaped structure. The sub-segments S22 and S23 may protrude from the sub-segment S21.

According to another embodiment of the present disclosure, the cross-sections of the first node 104P and the second node 104V may be rectangular, square, circular, oval, or polygonal. When the cross-sections of the first node 104P and the second node 104V are polygonal, at least four or more side wall facets may be included.

The side wall facets F11, F12 and F13 of the second node 104V may be surrounded by the linear buried electrode 120L and the extended buried electrodes 120E. The side wall facets F11, F12 and F13 of the second node 104V and the linear buried electrode 120L may horizontally overlap with each other. The side wall facets F11, F12 and F13 of the second node 104V and the linear buried electrode 120L may horizontally face each other. The side wall facets F11, F12 and F13 of the second node 104V and the extended buried electrodes 120E may horizontally overlap with each other. The side wall facets F11, F12 and F13 of the second node 104V and the extended buried electrodes 120E may horizontally face each other. The side wall facets F1 of the first node 104P and the linear buried electrodes 120L may horizontally overlap with each other. The side wall facets F1 of the first node 104P and the linear buried electrodes 120L may horizontally face each other.

A first doped region 106 and a second doped region 107 may be formed in each active region 104. The first doped region 106 may be formed in the second node 104V, and the second doped region 107 may be formed in the first node 104P. The first doped region 106 and the second doped region 107 may be regions doped with a conductive dopant. For example, the conductive dopant may include phosphorus (P), arsenic (As), antimony (Sb), or boron (B). The first doped region 106 and the second doped region 107 may be doped with dopants of the same conductivity type. The first doped region 106 and the second doped region 107 may be disposed in the active regions 104 on both sides of the trench 105. The bottom surfaces of the first doped region 106 and the second doped region 107 may be disposed in a predetermined depth from the top surface of the active region 104. The first doped region 106 and the second doped region 107 may contact the side wall of the trench 105. The bottom surfaces of the first doped region 106 and the second doped region 107 may be higher than the bottom surface of the trench 105. The first doped region 106 may be referred to as a ‘first source/drain region’, and the second doped region 107 may be referred to as a ‘second source/drain region’. The buried gate structure 100G may define a channel between the first doped region 106 and the second doped region 107. The channel may be defined along the profile of the trench 105.

The active region 104 may not include a fin region disposed below the bottom surface of the trench 105. The active region 104 may have a non-saddle fin structure. The role of the saddle fin may be replaced by the second node 104V, and thus the second node 104V may increase the channel width and improve the electrical characteristics.

According to another embodiment of the present disclosure, the first and second nodes 104P and 104V of the active region 104 may include an oxide semiconductor material, such as IGZO (InGaZnO). In this case, the first doped region 106 and the second doped region 107 may also include an oxide semiconductor material, such as IGZO. The first and second nodes 104P and 104V may be IGZO, and the first doped region 106 and the second doped region 107 may be oxide semiconductor materials having a lower resistance than the lower resistance of IGZO.

The gate dielectric layer 110 may be formed by a thermal oxidation process, a Chemical Vapor Deposition (CVD) process, or an Atomic Layer Deposition (ALD) process. The gate dielectric layer 110 may include a high-k material, a metal oxide, a silicon oxide, a silicon nitride, a silicon oxynitride, or a combination thereof. The high-k material may include a hafnium-containing material. The hafnium-containing material may include hafnium oxide, hafnium silicon oxide, hafnium silicon oxynitride, or a combination thereof. According to another embodiment of the present disclosure, the high-k material may include lanthanum oxide, lanthanum aluminum oxide, zirconium oxide, zirconium silicon oxide, zirconium silicon oxynitride, aluminum oxide, or a combination thereof. Other known high-k materials may be selectively used as the high-k material. The linear portion 110A and the non-linear portion 110B of the gate dielectric layer 110 may include the same material. According to another embodiment of the present disclosure, the gate dielectric layer 110 may include a stack of silicon oxide and a high-k material. The high-k material may include a material having a higher oxygen atom planar density than silicon oxide.

The gate electrode 120 may be a buried gate electrode that fills a portion of the trench 105. The gate electrode 120 may be disposed at a lower level than the top surface of the active region 104, i.e., the top surfaces of the first and second doped regions 106 and 107. The gate electrode 120 may include a semiconductor material, a metal-based material, or a combination thereof. The gate electrode 120 may include a metal, a metal nitride, or a combination thereof. The gate electrode 120 may include polysilicon, tantalum nitride (TaN), titanium nitride (TiN), tungsten (W), tungsten nitride (WN), molybdenum (Mo), ruthenium (Ru), or a combination thereof. The gate electrode 120 may be formed of titanium nitride alone. According to another embodiment of the present disclosure, the gate electrode 120 may have a high work function. Here, the high work function may refer to a work function which is higher than the mid-gap work function of silicon. A low work function may refer to a work function which is lower than the mid-gap work function of silicon. To be specific, the high work function may be a work function which is higher than approximately 4.5 eV, and the low work function may be a work function which is lower than approximately 4.5 eV. The gate electrode 120 may include P-type polysilicon or nitrogen-rich titanium nitride (TiN).

According to another embodiment of the present disclosure, the gate electrode 120 may have an increased high work function. The gate electrode 120 may include a metal silicon nitride. The metal silicon nitride may be a metal nitride that is doped with silicon. The gate electrode 120 may include a metal silicon nitride with a controlled silicon content. For example, the gate electrode 120 may include tantalum silicon nitride (TaSiN) or titanium silicon nitride (TiSiN). Titanium nitride may have a high work function, and silicon may be contained in the titanium nitride to further increase the work function of the titanium nitride. The titanium silicon nitride may have a controlled silicon content to have an increased high work function. According to another embodiment of the present disclosure, the gate electrode 120 may include titanium aluminum nitride (TiAlN).

The capping layer 130 may serve to protect the gate electrode 120. The capping layer 130 may fill the upper portion of the trench 105 over the gate electrode 120. The top surface of the capping layer 130 may be disposed at the same level as the top surfaces of the first and second doped regions 106 and 107.

The bit line 140 may be electrically connected to the first doped region 106 of the second node 104V. For example, the bit line 140 may be coupled to the first doped region 106 through the first contact node 141. The data storage element 150 may be electrically connected to the second doped region 107 of the first node 104P. For example, the data storage element 150 may be coupled to the second doped region 107 through the second contact node 151. The first contact node 141 may be referred to as a bit line contact plug, and the second contact node 151 may be referred to as a storage contact plug.

The first and second contact nodes 141 and 151 may include a semiconductor material, a doped semiconductor material, a metal-based material, a metal nitride-based material, a conductive metal oxide, or a combination thereof. For example, the first contact node 141 may include doped polysilicon, and the second contact node 151 may include a stacked structure of polysilicon, titanium nitride, and tungsten.

The bit line 140 may include a semiconductor material, a doped semiconductor material, a metal-based material, a metal nitride-based material, a conductive metal oxide, or a combination thereof. For example, the bit line 140 may include a stacked structure of titanium nitride and tungsten.

The data storage element 150 may include a memory element, such as a capacitor.

Referring back to FIG. 1F, the data storage element 150 may

include a first electrode SN, a second electrode PN over the first electrode SN, and a dielectric layer DE between the first electrode SN and the second electrode PN. The first electrode SN may have a pillar shape. According to another embodiment of the present disclosure, the first electrode SN may have a cylinder shape, a planar shape, or a pylinder shape. The pylinder shape may refer to a structure in which a pillar shape and a cylinder shape are merged.

The outer wall of the first electrode SN of the data storage element 150 may be supported by multi-layer-level supporters SP1 and SP2. The multi-layer-level supporters SP1 and SP2 may include a dielectric material, for example, silicon nitride, silicon carbon nitride, or a combination thereof. According to another embodiment of the present disclosure, the multi-layer-level supporters may include three or more supporters. The bottom portion of the first electrode SN of the data storage element 150 may be supported by an etch stop layer EST. The etch stop layer EST may include silicon nitride, silicon carbon nitride, or a combination thereof. The bottom portion of the first electrode SN of the data storage element 150 may penetrate the etch stop layer EST to be coupled to the second contact node 151.

The first electrode SN and the second electrode PN of the data storage element 150 may include a metal, a noble metal, a metal nitride, a conductive metal oxide, a conductive noble metal oxide, a metal carbide, a metal silicide, or a combination thereof. For example, the first electrode SN and the second electrode PN may include titanium (Ti), titanium nitride (TiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, or a combination thereof. The second electrode PN may also include a combination of a metal-based material and a silicon-based material. For example, the second electrode PN may be a stack of titanium nitride/silicon germanium/tungsten nitride (TiN/SiGe/WN). In the titanium nitride/silicon germanium/tungsten nitride (TiN/SiGe/WN) stack, silicon germanium may be a gap-fill material that fills the inside of the first electrode SN, titanium nitride (TiN) may serve as the second electrode PN of the data storage element 150, and tungsten nitride may be a low-resistance material.

The dielectric layer DE may be referred to as a capacitor dielectric layer or a memory layer. The dielectric layer DE may include silicon oxide, silicon nitride, a high-k material, or a combination thereof. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). According to another embodiment of the present disclosure, the dielectric layer DE may be formed of a composite layer including two or more layers of the aforementioned high-k materials.

The dielectric layer DE may be formed of zirconium (Zr)-based oxide. The dielectric layer DE may have a stacked structure including zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked over zirconium oxide (ZrO₂). The ZAZ stack may have a structure in which zirconium oxide (ZrO₂), aluminum oxide (Al₂O₃), and zirconium oxide (ZrO₂) are sequentially stacked. The ZA stack and the ZAZ stack may be referred to as zirconium oxide (ZrO₂)-based layers. According to another embodiment of the present disclosure, the dielectric layer DE may be formed of hafnium (Hf)-based oxide. The dielectric layer DE may have a stacked structure including hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked over hafnium oxide (HfO₂). The HAH stack may have a structure in which hafnium oxide (HfO₂), aluminum oxide (Al₂O₃), and hafnium oxide (HfO₂) are sequentially stacked. The HA stack and the HAH stack may be referred to as hafnium oxide (HfO₂)-based layers. In the ZA stack, ZAZ stack, HA stack, and HAH stack, aluminum oxide (Al₂O₃) may have a greater bandgap energy than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high-bandgap material having a greater bandgap energy than the high-k material. The dielectric layer DE may include silicon oxide (SiO₂) as a high bandgap material other than aluminum oxide (Al₂O₃). Since the dielectric layer DE includes a high bandgap material, leakage current may be suppressed. The high-bandgap material may be thinner than the high-k material. According to another embodiment of the present disclosure, the dielectric layer DE may include a stacked structure in which a high-k material and a high-bandgap material are alternately stacked. For example, the dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HZAZH (HfO₂/ZrO₂/Al₂O₃/ZrO₂/HfO₂) stack, a HAHA (HfO₂/Al₂O₃/HfO₂/Al₂O₃) stack, or a HAHAH (HfO₂/Al₂O₃/HfO₂/Al₂O₃/HfO₂) stack. In the above stacked structure, aluminum oxide (Al₂O₃) may be thinner than zirconium oxide (ZrO₂) and hafnium oxide (HfO₂).

According to another embodiment of the present disclosure, the dielectric layer DE may include a high-k material and a high bandgap material, and may have a laminated structure in which a plurality of high-k materials and a plurality of high bandgap materials are stacked, or a mixed structure in which a high-k material and a high bandgap material are intermixed.

According to another embodiment of the present disclosure, the dielectric layer DE may include a ferroelectric material, an anti-ferroelectric material, or a combination thereof. For example, the dielectric layer DE may include hafnium zirconium oxide (HfZrO).

According to another embodiment of the present disclosure, the dielectric layer DE may include a combination of a high-k material and a ferroelectric material, a combination of a high-k material and an anti-ferroelectric material, a high-k material, or a combination of a ferroelectric material and an anti-ferroelectric material.

According to another embodiment of the present disclosure, an interface control layer may be further formed between the first electrode SN and the dielectric layer DE to improve the leakage current. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode PN and the dielectric layer DE.

According to another embodiment of the present disclosure, the data storage element 150 may be a thyristor, a phase change material, a magnetic tunnel junction (MTJ), or a variable resistance material.

Referring to FIGS. 1A to 1F, the semiconductor device 100 may include a plurality of memory cells, and the neighboring memory cells may be separated from each other by an isolation layer 102. One memory cell may be formed over one active region 104. In each memory cell, one gate electrode 120 may be formed in one active region 104, and this may be referred to as a memory cell of a ‘1G1A (one Gate-one Active) structure.’ In the memory cell of the 1G1A structure, the bit line 140 may be coupled to one active region 104, so one memory cell may be coupled to one bit line 140. The memory cell of the 1G1A structure may include 1T1C (one Transistor-one Capacitor). As a comparative example, in a typical DRAM, two memory cells may be formed in one active region, and two gate electrodes may be formed in one active region, and two neighboring memory cells may share one bit line.

A semiconductor device 100 including a memory cell of the 1G1A structure may include the active regions 104 that are arranged in a unidirection of the third direction D3. The isolation layer 102, the second node 104V, the gate dielectric layer 110, the gate electrode 120, and the first node 104P may be arranged sequentially in the unidirection of the third direction D3.

The semiconductor device 100 including the memory cell of the 1G1A structure may include an active region 104 having an asymmetrical structure, a gate dielectric layer 110 having an asymmetrical structure, and a gate electrode 120 having an asymmetrical structure. The first node 104P and the second node 104V may be asymmetrical to each other. The first node 104P may include a single-side wall facet F1 facing the gate electrode 120, and the second node 104V may include a multi-side wall facet F11, F12 and F13 facing the gate electrode 120. The gate dielectric layer 110 may include a linear portion 110A covering the single-side wall facet F1, and a non-linear portion 110B covering the multi-side wall facets F11, F12 and F13. The gate electrode 120 may include a linear buried electrode 120L facing the single-side wall facet F1 and extended buried electrodes 120E facing the multi-side wall facets F11, F12 and F13. The gate electrode 120 may include a flat-type first segment 120S1 facing the single-side wall facet F1 and a ∩-shaped bent-type second segment 120S2 facing the multi-side wall facets F11, F12 and F13.

In another embodiment, the semiconductor device 100 may include a pillar-shaped node 104P having a plurality of first side wall facets F1 to F5, a vertical fin 104V having a plurality of second side wall facets F11 to F15, and a conductive structure 120 buried between the pillar-shaped node 104P and the vertical fin 104V, wherein the conductive structure 120 may include a first segment 120S1 facing one first side wall facet among the first side wall facets, and second segments 120S2 extending from the first segment 120S1 and covering at least three second side wall facets F11, F12 and F13 among the second side wall facets F11 to F15.

According to the above-described embodiment of the present disclosure, since the second node 104V of the vertical fin structure is formed, gate controllability may be secured, and the influence of the row hammering may be minimized by decreasing the height of the passing gate PG.

Further, since the extended buried electrodes 120E of the gate electrode 120 surround the second node 104V, leakage current such as gate-induced drain leakage (GIDL) may be prevented, and also, since the second node 104V of the vertical fin structure is coupled to the bit line 140, the influence of the gate-induced drain leakage (GIDL) may be minimized.

Further, since the second node 104V of the vertical fin structure is formed by removing the saddle fin, transistor controllability may be secured.

Further, as the vertical fin structure is applied, it is possible to secure a low margin of a threshold voltage due to the increase in the channel length, and also it is possible to improve refresh/row hammering due to the decrease in the fin height.

Further, since the second node 104V of the vertical fin structure includes a plurality of side wall facets, the side wall surface area of the second node 104V may be increased.

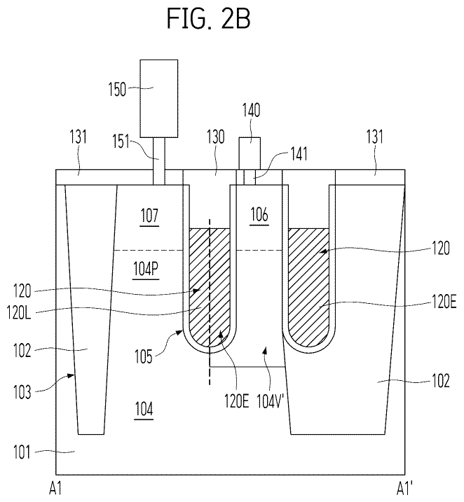

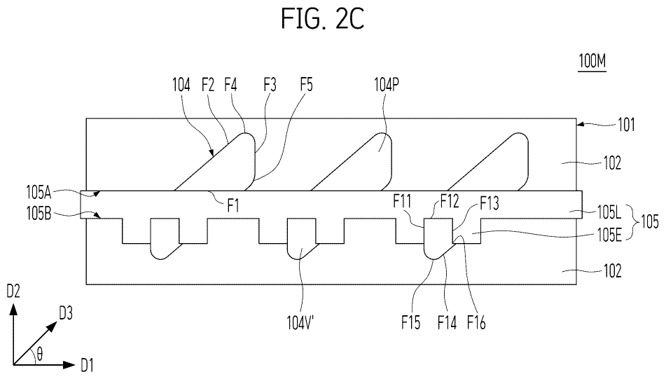

FIG. 2A is a plan view illustrating a semiconductor device in accordance with another embodiment of the present disclosure. FIG. 2B is a cross-sectional view taken along a line A1-A1′ shown in FIG. 2A. FIG. 2C is a plan view illustrating a trench and an active region shown in FIGS. 2A and 2B.

Referring to FIGS. 2A to 2C, the semiconductor device 100M may include a substrate 101 and a gate electrode 120. The semiconductor device 100M may be similar to the semiconductor device 100 illustrated in FIGS. 1A to 1F.

The semiconductor device 100M may include a plurality of memory cells. The semiconductor device 100M may further include a bit line 140 and a data storage element 150, as illustrated in FIGS. 1A and 1B. The semiconductor device 100M may include a memory cell of the 1G1A structure.

The semiconductor device 100M may include a trench 105 formed in the substrate 101, a gate dielectric layer 110 covering the bottom surface and a side wall of the trench 105, a gate electrode 120 filling a portion of the trench 105 over the gate dielectric layer 110, and a capping layer 130 over the gate electrode 120.

The isolation layer 102 and the active regions 104 may be formed over the substrate 101. The active regions 104 may be defined by the isolation layer 102. A trench 105 may be formed in the substrate 101.

The active regions 104 may include strips and may be arranged in the form of an array. The array of the active regions 104 may include a row array. The row array of the active regions 104 may include active regions 104 that are arranged in the second direction D2. The longitudinal direction of the active regions 104, i.e., the third direction D3, may be non-orthogonal to the first direction D1 and the second direction D2 to form an intersection angle (θ). The intersection angle (θ) between the second direction D2 and the third direction D3 of the active region 104 may range from approximately 10° to 80°, but the concept and spirit of the present embodiment may not be limited thereto. The range of the intersection angle (θ) may be affected by parameters, such as the area of the active region 104, the line width of the bit line 140, and the line width of the buried gate structure 100G. From the perspective of a top view, the cross-section of each active region 104 may be a parallelogram, for example, a parallelogram with rounded edges. According to another embodiment of the present disclosure, the active regions 104 may further include a column array, and the column array may include active regions 104 that are arranged in the first direction D1.

The active regions 104 may be arranged in a unidirection of the third direction D3.

Each of the trenches 105 may divide each of the active regions 104 arranged in the second direction D2 into a first node 104P and a second node 104V′. The first and second nodes 104P and 104V′ may be referred to as first and second contact regions, respectively. The first node 104P and the second node 104V′ may be asymmetrical to each other in the third direction D3. The size (or volume) of the first node 104P may be greater than the size (or volume) of the second node 104V′. The length of the first node 104P in the third direction D3 may be greater than the length of the second node 104V′ in the third direction D3. According to another embodiment of the present disclosure, the size (or volume) of the first node 104P and the size (or volume) of the second node 104V′ may be the same.

Each of the first node 104P and the second node 104V′ may include a plurality of side wall facets. Each of the first node 104P and the second node 104V′ may be referred to as a multi-side wall facet active node. The first and second nodes 104P and 104V′ may include a semiconductor material. The first and second nodes 104P and 104V′ may be formed of a material containing silicon. Each of the first and second nodes 104P and 104V′ may include silicon, single crystalline silicon, polysilicon, amorphous silicon, silicon germanium, single crystalline silicon germanium, polycrystalline silicon germanium, carbon-doped silicon, a combination thereof, or a multi-layer thereof.

Referring back to FIG. 2C, the first node 104P may include a plurality of side wall facets F1, F2, F3, F4 and F5. The side wall facets F1, F2, F3, F4 and F5 of the first node 104P may include a gate-side facet F1 and an isolation layer-side facets F2, F3, F4 and F5. The gate-side facet F1 may directly contact the gate dielectric layer 110 and may be adjacent to the gate electrode 120. The isolation layer-side facets F2, F3, F4 and F5 may directly contact the isolation layer 102. In another embodiment, the side wall facets F1, F2, F3, F4 and F5 of the first node 104P may include linear side wall facets F1, F2 and F3 and non-linear side wall facets F4 and F5. The linear side wall facets F1, F2 and F3 may include flat surfaces, and the non-linear side wall facets F4 and F5 may include rounded surfaces. The linear side wall facet F1 of the first node 104P may be a gate-side facet, and the linear side wall facets F2 and F3 and the non-linear side wall facets F4 and F5 may be isolation layer-side facets.

Referring back to FIG. 2C, the second node 104V′ may include a plurality of side wall facets F11, F12, F13, F14 and F15. The second node 104V′ may further include an additional side wall facet F16.

The first side wall 105A of the trench 105 may be provided by the side wall facets F1 of the first nodes 104P and the isolation layer 102. The second side wall 105B of the trench 105 may be provided by the side wall facets F11, F12 and F13 of the second nodes 104V′ and the isolation layer 102.

The trench 105 may include a linear trench portion 105L and a plurality of extended trench portions 105E extending from the linear trench portion 105L. The linear trench portion 105L of the trench 105 may extend in the first direction D1, and the extended trench portions 105E of the trench 105 may extend in the second direction D2. The linear trench portion 105L of the trench 105 may expose the side wall facet F1 of the first node 104P and the side wall facet F12 of the second node 104V′. The extended trench portions 105E of the trench 105 may expose the side wall facets F11 and F13 of the second node 104V′. The linear trench portion 105L and the extended trench portions 105E of the trench 105 may expose the side wall facets F11, F12 and F13 of the second node 104V′. The linear trench portion 105L may cross the isolation layer 102 in the first direction D1. The extended trench portions 105E may extend into the isolation layer 102 in the second direction D2.

As described above, one side wall facet F1 among the side wall facets F1 to F5 of the first node 104P may be exposed by the linear trench portion 105L of the trench 105, and four side wall facets F11, F12, F13 and F16 among the side wall facets F11 to F16 of the second node 104V′ may be exposed. The surface area of the side wall facet F1 of the first node 104P may be equal to the total surface area of the side wall facets F11, F12, F13 and F16 of the second node 104V′. According to another embodiment of the present disclosure, the total surface area of the side wall facets F11, F12, F13 and F16 of the second node 104V′ may be greater than the surface area of the side wall facet F1 of the first node 104P.

The second node 104V′ may be referred to as a vertical fin, and the side wall facets F11, F12, F13 and F16 of the second node 104V′ may be referred to as a multi-facet fin.

The gate dielectric layer 110 may be formed on the side wall and bottom surface of the trench 105. The gate dielectric layer 110 may include a linear portion 110A and a non-linear portion 110B. The linear portion 110A of the gate dielectric layer 110 may be formed on the first side wall 105A of the trench 105. The non-linear portion 110B of the gate dielectric layer 110 may be formed on the second side wall 105B of the trench 105. The linear portion 110A of the gate dielectric layer 110 may cover the side wall facet F1 of the first node 104P. The non-linear portion 110B of the gate dielectric layer 110 may cover the side wall facets F11, F12 and F13 of the second node 104V′.

The gate electrode 120 may include a linear buried electrode 120L and a plurality of extended buried electrodes 120E. The linear buried electrode 120L may fill a portion of the linear trench portion 105L over the gate dielectric layer 110, and the extended buried electrodes 120E may fill a portion of the extended trench portions 105E over the gate dielectric layer 110.

In another embodiment, the gate electrode 120 may have a comb-shaped structure including a plurality of segments 120S1 and 120S2, as illustrated in FIG. 1E. For example, the gate electrode 120 may include a first segment 120S1 and a second segment 120S2. The first segment 120S1 may face the first node 104P, and the second segment 120S2 may face the second node 104V′. The second segment 120S2 of the gate electrode 120 may have a ∩ shape that surrounds a portion of the second node 104V′. The second segment 120S2 may include three sub-segments S21, S22 and S23. The sub-segment S21 may correspond to the body of the comb-shaped structure, and the sub-segments S22 and S23 may correspond to the teeth of the comb-shaped structure. The sub-segments S22 and S23 may protrude from the sub-segment S21.

According to another embodiment of the present disclosure, the cross-sections of the first node 104P and the second node 104V′ may be rectangular, square, circular, oval or polygonal. When the cross-sections of the first node 104P and the second node 104V′ are polygonal, the cross-sections may include at least four or more side wall facets.

The side wall facets F11, F12 and F13 of the second node 104V′ may be surrounded by the linear buried electrode 120L and the extended buried electrodes 120E. The side wall facets F11, F12 and F13 of the second node 104V′ and the linear buried electrode 120L may horizontally overlap with each other. The side wall facets F11, F12 and F13 of the second node 104V′ and the linear buried electrode 120L may horizontally face each other. The side wall facets F11, F12 and F13 of the second node 104V′ and the extended buried electrodes 120E may horizontally overlap with each other. The side wall facets F11, F12 and F13 of the second node 104V′ and the extended buried electrodes 120E may horizontally face each other. The side wall facet F1 of the first node 104P and the linear buried electrode 120L may horizontally overlap with each other. The side wall facet F1 of the first node 104P and the linear buried electrode 120L may horizontally face each other.

A first doped region 106 and a second doped region 107 may be formed in each active region 104. The first doped region 106 may be formed in the second node 104V′, and the second doped region 107 may be formed in the first node 104P. The first doped region 106 and the second doped region 107 may be regions doped with a conductive dopant. For example, the conductive dopant may include phosphorus (P), arsenic (As), antimony (Sb), or boron (B). The first doped region 106 and the second doped region 107 may be doped with dopants of the same conductivity type. The first doped region 106 and the second doped region 107 may be disposed in the active regions 104 on both sides of the trench 105. The bottom surfaces of the first doped region 106 and the second doped region 107 may be disposed in a predetermined depth from the top surface of the active region 104. The first doped region 106 and the second doped region 107 may contact the side wall of the trench 105. The bottom surfaces of the first doped region 106 and the second doped region 107 may be higher than the bottom surface of the trench 105. The first doped region 106 may be referred to as a ‘first source/drain region’, and the second doped region 107 may be referred to as a ‘second source/drain region’. A channel may be defined between the first doped region 106 and the second doped region 107 due to the buried gate structure 100G. The channel may be defined along the profile of the trench 105.

The active region 104 may not include a fin region disposed below the bottom surface of the trench 105. The active region 104 may have a non-saddle fin structure. The role of the saddle fin may be replaced by the second node 104V′, and thus, the second node 104V′ may increase the channel width and improve the electrical characteristics.

Referring to FIGS. 2A to 2C, a portion of the bottom portion of the second node 104V′ may extend to overlap with the bottom portion of the extended buried electrode 120E. The second node 104V′ may have an L shape.

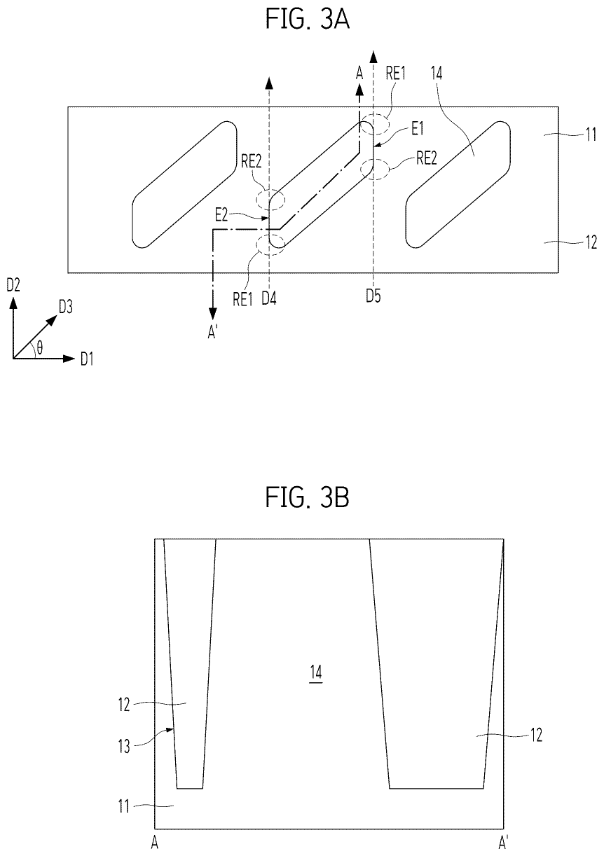

FIGS. 3A, 4A, 5A, 6A and 7A are plan views illustrating a method for fabricating a semiconductor device in accordance with an embodiment of the present disclosure. FIGS. 3B, 4B, 5B, 6B and 7B are cross-sectional views taken along a line A-A′ shown in FIGS. 3A, 4A, 5A, 6A and 7A.

Referring to FIGS. 3A and 3B, an isolation layer 12 and a plurality of active regions 14 may be formed over a substrate 11. The substrate 11 may be a material appropriate for semiconductor processing. The substrate 11 may include at least one of a conductive material, a dielectric material, and a semiconductor material. Diverse materials may be formed over the substrate 11. The substrate 11 may include a semiconductor substrate. The substrate 11 may be formed of a material containing silicon. The substrate 11 may include silicon, single crystalline silicon, polysilicon, amorphous silicon, silicon germanium, single crystalline silicon germanium, polycrystalline silicon germanium, carbon-doped silicon, a combination thereof, or a multi-layer thereof. The substrate 11 may include another semiconductor material, such as germanium. The substrate 11 may include a III/V-group semiconductor substrate, for example, a compound semiconductor substrate, such as gallium arsenide (GaAs). The substrate 11 may include a Silicon-On-Insulator (SOI) substrate.

A plurality of active regions 14 may be defined by the isolation layer 12. The isolation layer 12 may be formed by a STI (Shallow Trench Isolation) process. For example, the isolation layer 12 may be formed by etching the substrate 11 to form an isolation trench 13, and then filling the isolation trench 13 with a dielectric material. The isolation layer 12 may include silicon oxide, silicon nitride, or a combination thereof. A Chemical Vapor Deposition (CVD) process or another deposition process may be performed to fill the isolation trench 13 with a dielectric material. A planarization process, such as Chemical-Mechanical Polishing (CMP), may be performed additionally.

Each active region 14 may have an island shape. Each active region 14 may include a first end surface E1 and a second end surface E2 facing the first end surface E1. Each active region 14 may further include a plurality of rounded edges RE1 and RE2. The curvature of the first round edges RE1 and the curvature of the second round edges RE2 may be different from each other.

The active regions 14 may be regularly arranged in the first direction D1 to form a row array. According to another embodiment of the present disclosure, the active regions 14 may be regularly arranged in the second direction D2 or may be regularly arranged in the third direction D3. The active regions 14 disposed adjacent to each other in the second direction D2 may be parallel to the third direction D3. The first end surfaces E1 of the active regions 14 may be arranged in a fourth direction D4, and the second end surfaces E2 of the active regions 14 may be arranged in a fifth direction D5. The fourth direction D4 and the fifth direction D5 may be directions that are parallel to the second direction D2. The first end surfaces E1 and the second end surfaces E2 of the active regions 14 may be arranged in the third direction D3. Each of the active regions 14 may extend in a unidirection of the third direction D3.

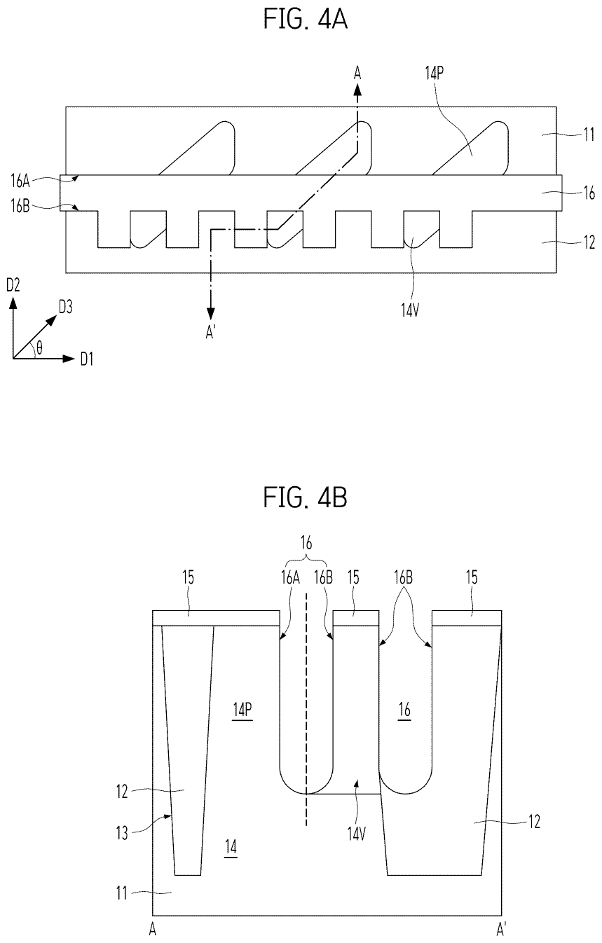

Referring to FIGS. 4A and 4B, a trench 16 may be formed in the substrate 11. The trench 16 may be formed in a line shape that crosses the active regions 14 and the isolation layer 12. For example, the trench 16 may extend in the first direction D1.

The trench 16 may be formed by an etching process of the substrate 11 using the hard mask layer 15 as an etching mask. The hard mask layer 15 may be formed over the substrate 11 and may have a plurality of openings. The hard mask layer 15 may be formed of a material having an etching selectivity with respect to the substrate 11. The hard mask layer 15 may be silicon oxide, such as Tetra-Ethyl-Ortho-Silicate (TEOS). The trench 15 may be formed shallower than the isolation trench 13. The depth of the trench 16 may be sufficiently deep to increase the average cross-sectional area of the subsequent gate electrode. Accordingly, the resistance of the gate electrode may be decreased. The bottom edge of the trench 16 according to another embodiment of the present disclosure may have a curvature.

The trench 16 may divide each active region 14 into two nodes 14P and 14V. For example, each active region 14 may be divided into a first node 14P and a second node 14V, and the first node 14P and the second node 14V may be asymmetrical to each other in the third direction D3. Each of the first node 14P and the second node 14V may include a plurality of side wall facets. As for the side wall facets, FIG. 1D may be referred to.

The trench 16 may include a first side wall 16A and a second side wall 16B. The first side wall 16A and the second side wall 16B of the trench 16 may be provided by the side wall facets of the first and second nodes 14P and 14V and the isolation layer 12. The first side wall 16A of the trench 16 may have a linear shape extending in the first direction D1. The second side wall 16B of the trench 16 may have a non-linear shape or a wave shape extending in the first direction D1.

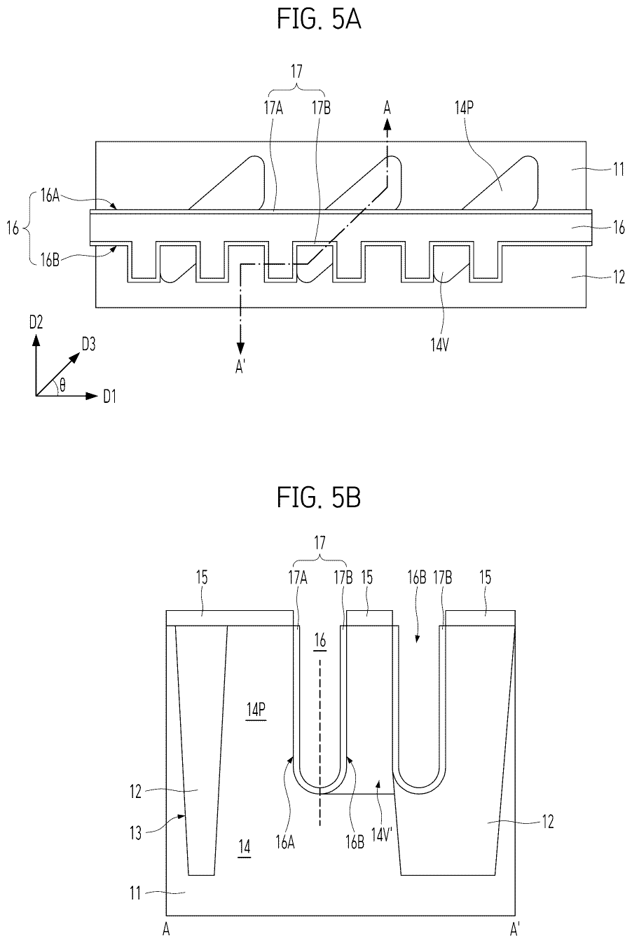

Referring to FIGS. 5A and 5B, a gate dielectric layer 17 may be formed on the first and second side walls 16A and 16B of the trench 16. Before the gate dielectric layer 17 is formed, etching damage on the surface of the trench 15 may be cured. For example, after a sacrificial oxide is formed by a thermal oxidation process, the sacrificial oxide may be removed. The gate dielectric layer 17 may be formed by a thermal oxidation process. The gate dielectric layer 17 may include silicon oxide.

The gate dielectric layer 17 may be selectively formed on the side wall facets of the first nodes 14P and the side wall facets of the second nodes 14V.

The gate dielectric layer 17 may include first gate dielectric layers 17A and second gate dielectric layers 17B. The first gate dielectric layers 17A may be formed on the side wall facets of the first nodes 14P. The second gate dielectric layers 17B may be selectively formed on the side wall facets of the second nodes 14V. The thickness of the first gate dielectric layers 17A and the thickness of the second gate dielectric layers 17B may be the same.

According to another embodiment of the present disclosure, the gate dielectric layer 17 may further include an additional gate dielectric layer. The additional gate dielectric layer may be formed over the first and second gate dielectric layers 17A and 17B. The additional gate dielectric layer may be formed by a Chemical Vapor Deposition (CVD) process or an Atomic Layer Deposition (ALD) process. The additional gate dielectric layer formed by the deposition method may include a high-k material, an oxide, a nitride, an oxynitride, or a combination thereof. The high-k material may include a hafnium-containing material. The hafnium-containing material may include hafnium oxide, hafnium silicon oxide, hafnium silicon oxynitride, or a combination thereof. According to another embodiment of the present disclosure, the high-k material may include lanthanum oxide, lanthanum aluminum oxide, zirconium oxide, zirconium silicon oxide, zirconium silicon oxynitride, aluminum oxide, or a combination thereof. Other known high-k materials may be selectively used as the high-k material.

According to another embodiment of the present disclosure, the gate dielectric layer may include a stack of silicon oxide and a high-k material. The silicon oxide may be the first and second gate dielectric layers 17A and 17B, and the high-k material may be an additional gate dielectric layer. The high-k material may include a material having a higher oxygen atom planar density than silicon oxide.

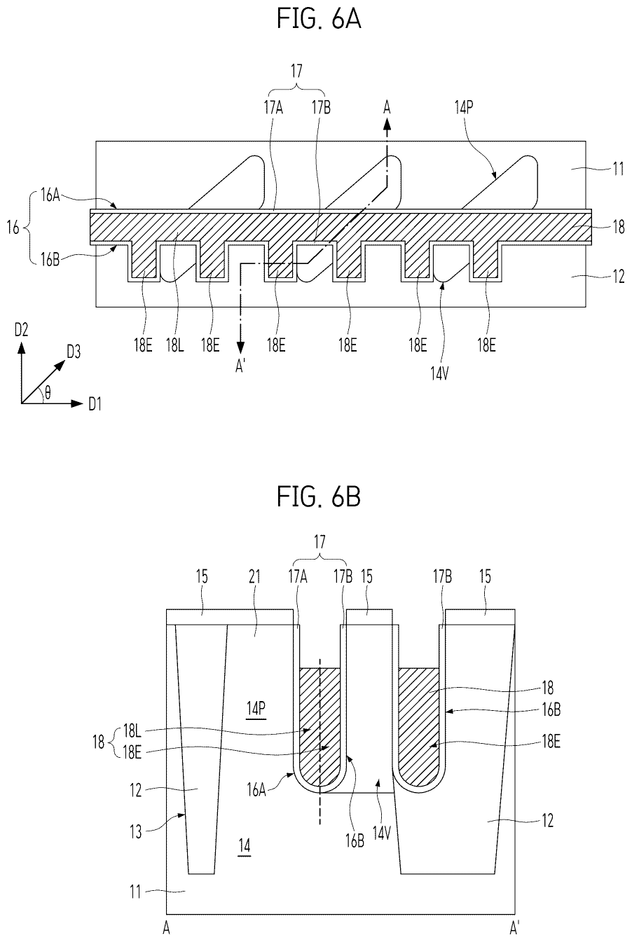

Referring to FIGS. 6A and 6B, a gate electrode 18 may be formed over the gate dielectric layer 17 to fill a portion of the trench 16.

The gate electrode 18 may include a linear portion 18L and a plurality of extended portions 18E. The linear portion 18L of the gate electrode 18 may extend in the first direction D1. The extended portions 18E of the gate electrode 18 may protrude from the linear portion 18L in the second direction D2. By combining the linear portion 18L and the extended portions 18E, the gate electrode 18 may cover at least three or more side walls among the side walls of the second node 14V.

The gate electrode 18 may be disposed at a lower level than the top surface of the active region 14. The gate electrode 18 may include a metal-based material. The gate electrode 18 may include a semiconductor material, a metal, a metal nitride, or a combination thereof. The gate electrode 18 may include polysilicon, tantalum nitride (TaN), titanium nitride (TiN), tungsten (W), tungsten nitride (WN), molybdenum (Mo), ruthenium (Ru), or a combination thereof. The gate electrode 18 may be formed of a stack of titanium nitride and tungsten, a stack of titanium nitride and polysilicon, or titanium nitride alone. According to another embodiment of the present disclosure, the gate electrode 18 may have a high work function. Here, the high work function may refer to a work function which is higher than the mid-gap work function of silicon. A low work function may refer to a work function which is lower than the mid-gap work function of silicon. To be specific, the high work function may be a work function which is higher than approximately 4.5 eV, and the low work function may be a work function which is lower than approximately 4.5 eV. The gate electrode 18 may include P-type polysilicon or nitrogen-rich titanium nitride (TiN).

According to another embodiment of the present disclosure, the gate electrode 18 may have an increased high work function. The gate electrode 18 may include a metal silicon nitride. The metal silicon nitride may be a metal nitride that is doped with silicon. The gate electrode 18 may include a metal silicon nitride with a controlled silicon content. For example, the gate electrode 18 may include tantalum silicon nitride (TaSiN) or titanium silicon nitride (TiSiN). Titanium nitride may have a high work function, and silicon may be contained in the titanium nitride to further increase the work function of the titanium nitride. The titanium silicon nitride may have a controlled silicon content to have an increased high work function. According to another embodiment of the present disclosure, the gate electrode 18 may include titanium aluminum nitride (TiAlN).

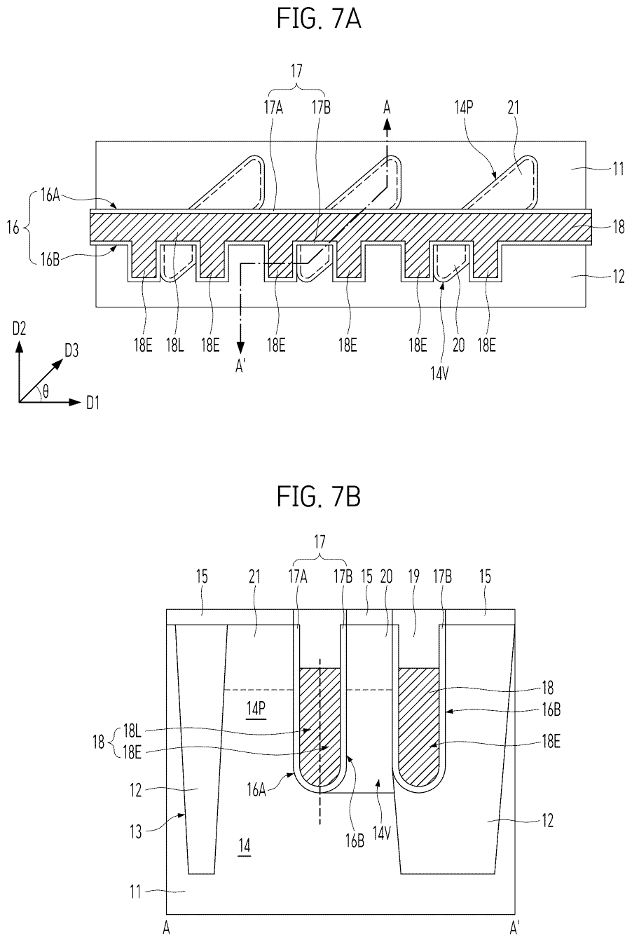

Referring to FIGS. 7A and 7B, a capping layer 19 may be formed over the gate electrode 18. The capping layer 19 may serve to protect the gate electrode 18. The capping layer 19 may fill an upper portion of the trench 15 over the gate electrode 18. The top surface of the capping layer 19 may be disposed at the same level as the top surface of the hard mask layer GM. The capping layer 19 may include silicon oxide, silicon nitride, or a combination thereof. According to another embodiment of the present disclosure, the capping layer 19 may include fluorine-containing silicon oxide, fluorine-containing silicon nitride, or a combination thereof.

After the capping layer 19 is formed, first doped regions 20 and second doped regions 21 may be formed in the first nodes 14P and the second nodes 14V, respectively. The first doped regions 20 may be formed in the second nodes 14V, and the second doped regions 21 may be formed in the first nodes 14P. The first and second doped regions 20 and 21 may be referred to as source/drain regions.

The first doped region 20 and the second doped region 21 may be regions doped with a conductive dopant. For example, the conductive dopant may include phosphorus (P), arsenic (As), antimony (Sb), or boron (B). The first doped region 20 and the second doped region 21 may be doped with dopants of the same conductivity type. The first doped region 20 and the second doped region 21 may be disposed in the active regions 14 on both sides of the trench 16. The bottom surfaces of the first doped region 20 and the second doped region 21 may be disposed in a predetermined depth from the top surface of the active regions 14. The bottom surfaces of the first doped region 20 and the second doped region 21 may be higher than the bottom surface of the trench 16. The first doped region 20 may be referred to as a ‘first source/drain region’, and the second doped region 21 may be referred to as a ‘second source/drain region’. A channel may be defined between the first doped region 20 and the second doped region 21 due to the gate electrode 18. The channel may be defined along the profile of the trench 16.

Subsequently, a first contact node 141, a bit line 140, a second contact node 151, and a data storage element 150 as illustrated in FIGS. 1A and 1B may be sequentially formed. For example, a process of forming the first contact node 141 and the bit line 140 coupled to the first doped region 20 and a process of forming the second contact node 151 and the data storage element 150 coupled to the second doped region 21 may be performed.

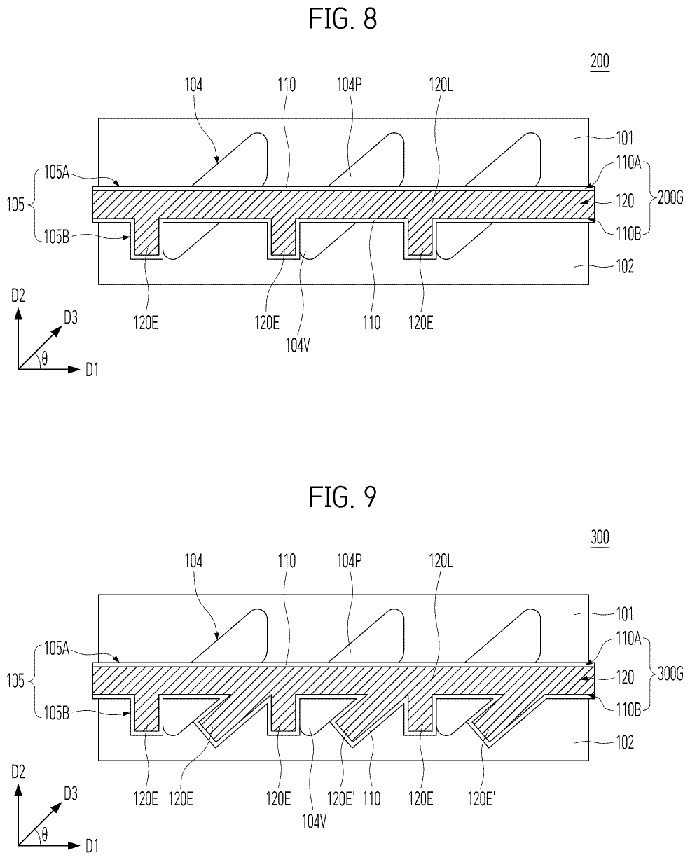

FIGS. 8 to 12 are plan views illustrating semiconductor devices in accordance with other embodiments of the present disclosure. The semiconductor devices 200, 300, 400, 500 and 600 illustrated in FIGS. 8 to 12 may be similar to the semiconductor device 100 of FIGS. 1A to 1F. As to the detailed description on the constituent elements also appearing in FIGS. 1A to 1F, the description of FIGS. 1A to 1F may be referred to.

Referring to FIG. 8, the semiconductor device 200 may include a substrate 101, an isolation layer 102, active regions 104, and a buried gate structure 200G. The active regions 104 may include strips and may be arranged in the form of an array. The array of the active regions 104 may include a row array. The row array of the active regions 104 may include active regions 104 that are arranged in the first direction D1. The longitudinal direction of the active regions 104, i.e., the third direction D3, may be non-orthogonal to the first direction D1 and the second direction D2 to form an intersection angle (θ). The intersection angle (θ) between the first direction D1 and the third direction D3 of the active region 104 may range from approximately 10° to 80°, but the concept and spirit of the present embodiment may not be limited thereto.

The buried gate structure 200G may extend in the first direction D1. The buried gate structure 200G may include a trench 105 formed in the substrate 101, a gate dielectric layer 110 covering the bottom surface and side walls of the trench 105, and a gate electrode 120 filling a portion of the trench 105 over the gate dielectric layer 110. The gate dielectric layer 110 may be formed on the side walls and the bottom surface of the trench 105. The gate dielectric layer 110 may include a linear portion 110A and a non-linear portion 110B. The linear portion 110A of the gate dielectric layer 110 may be formed on the first side wall 105A of the trench 105. The non-linear portion 110B of the gate dielectric layer 110 may be formed on the second side wall 105B of the trench 105.

The gate electrode 120 may include a linear buried electrode (i.e., a linear portion of the gate electrode 120) 120L and a plurality of extended buried electrodes (i.e., extended portions of the gate electrode 120) 120E. The linear buried electrode 120L may fill a portion of the linear trench portion 105L over the gate dielectric layer 110, and the extended buried electrodes 120E may fill a portion of the extended trench portions 105B over the gate dielectric layer 110. Based on one second node 104V, the extended buried electrode 120E may have a single structure.

Two side wall facets among the side wall facets of the second node 104V may be covered by the linear buried electrodes 120L and the extended buried electrodes 120E.

Referring to FIG. 9, the semiconductor device 300 may include a substrate 101, an isolation layer 102, active regions 104, and a buried gate structure 300G. The active regions 104 may include strips and may be arranged in the form of an array. The array of the active regions 104 may include a row array. The row array of the active regions 104 may include active regions 104 that are arranged in the first direction D1. The longitudinal direction of the active regions 104, i.e., the third direction D3, may be non-orthogonal to the first direction D1 and the second direction D2 to form an intersection angle (θ). The intersection angle (θ) between the first direction D1 and the third direction D3 of the active regions 104 may range from approximately 10° to 80°, but the concept and spirit of the present embodiment may not be limited thereto.

The buried gate structure 300G may extend in the first direction D1. The buried gate structure 300G may include a trench 105 formed in the substrate 101, a gate dielectric layer 110 covering the bottom surface and side walls of the trench 105, and a gate electrode 120 filling a portion of the trench 105 over the gate dielectric layer 110. The gate dielectric layer 110 may be formed on the side walls and bottom surface of the trench 105. The gate dielectric layer 110 may include a linear portion 110A and a non-linear portion 110B. The linear portion 110A of the gate dielectric layer 110 may be formed on the first side wall 105A of the trench 105. The non-linear portion 110B of the gate dielectric layer 110 may be formed on the second side wall 105B of the trench 105.

The gate electrode 120 may include a linear buried electrode

(i.e., a linear portion of the gate electrode 120) 120L, a plurality of extended buried electrodes (i.e., extended portions of the gate electrode 120) 120E, and a plurality of additional extended buried electrodes 120E′. The linear buried electrode 120L may fill a portion of the trench 105 over the gate dielectric layer 110, and the extended buried electrodes 120E and the additional extended buried electrodes 120E′ may cover some of the side wall facets of the second node 104V over the gate dielectric layer 110. Based on one second node 104V, a double structure of the extended buried electrode 120E and the additional extended buried electrode 120E′ may face one second node 104V, and the extended buried electrodes 120E and the additional extended buried electrode 120E′ may be asymmetrical to each other.

Three side wall facets among the side wall facets of the second node 104V may be covered by the linear buried electrodes 120L, the extended buried electrodes 120E, and the additional extended buried electrodes 120E′.

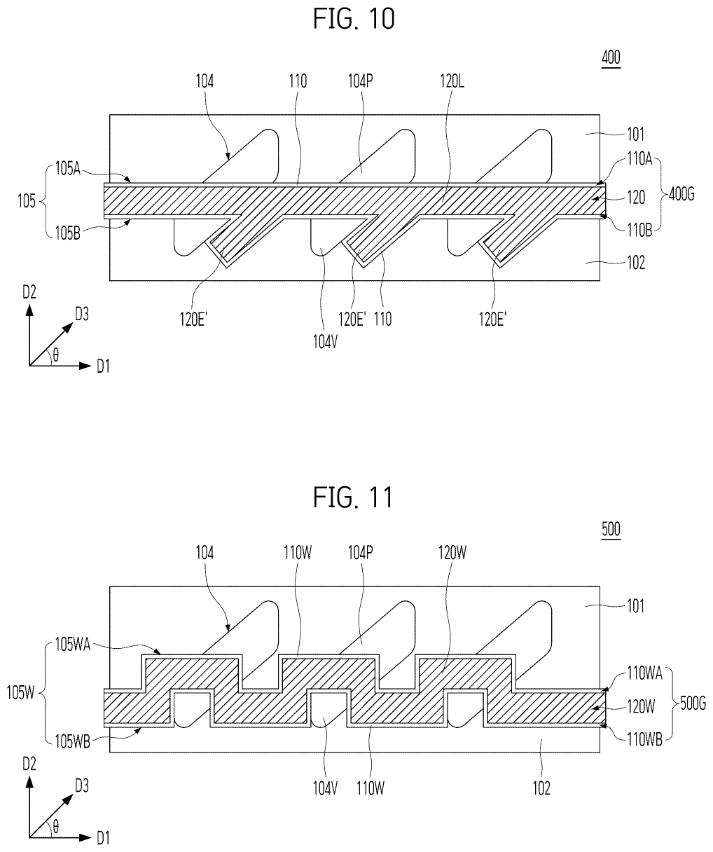

Referring to FIG. 10, the semiconductor device 400 may include a substrate 101, an isolation layer 102, active regions 104, and a buried gate structure 400G. The active regions 104 may include strips and may be arranged in the form of an array. The array of the active regions 104 may include a row array. The row array of the active regions 104 may include active regions 104 that are arranged in the first direction D1. The longitudinal direction of the active regions 104, i.e., the third direction D3, may be non-orthogonal to the first direction D1 and the second direction D2 to form an intersection angle (θ). The intersection angle (θ) between the first direction D1 and the third direction D3 of the active regions 104 may range from approximately 10° to 80°, but the concept and spirit of the present embodiment may not be limited thereto.

The buried gate structure 400G may extend in the first direction D1. The buried gate structure 400G may include a trench 105 formed in the substrate 101, a gate dielectric layer 110 covering the bottom surface and side walls of the trench 105, and a gate electrode 120 filling a portion of the trench 105 over the gate dielectric layer 110. The gate dielectric layer 110 may be formed on the side walls and bottom surface of the trench 105. The gate dielectric layer 110 may include a linear portion 110A and a non-linear portion 110B. The linear portion 110A of the gate dielectric layer 110 may be formed on the first side wall 105A of the trench 105. The non-linear portion 110B of the gate dielectric layer 110 may be formed on the second side wall 105B of the trench 105.

The gate electrode 120 may include a linear buried electrode (i.e., a linear portion of the gate electrode 120) 120L and a plurality of additional extended buried electrodes (i.e., extended portions of the gate electrode 120) 120E′. Based on one second node 104V, the additional extended buried electrode 120E may have a single structure.

Referring to FIG. 11, a semiconductor device 500 may include a substrate 101, an isolation layer 102, active regions 104, and a buried gate structure 500G. The active regions 104 may include strips and may be arranged in the form of an array. The array of active regions 104 may include a row array. The row array of active regions 104 may include active regions 104 that are arranged in the first direction D1. The longitudinal direction of the active regions 104, i.e., the third direction D3, may be non-orthogonal to the first direction D1 and the second direction D2 to form an intersection angle (θ). The intersection angle (θ) between the first direction D1 and the third direction D3 of the active region 104 may range from approximately 10° to 80°, but the concept and spirit of the present embodiment may not be limited thereto.

The buried gate structure 500G may be formed in a gate trench 105W. The buried gate structure 500G may include a gate dielectric layer 110W and a gate electrode 120W. The gate trench 105W and the gate electrode 120W may have a continuous wave shape. The gate electrode 120W may have a square wave shape. The gate trench 105W may include a wave-shaped first side wall 105WA and a wave-shaped second side wall 105WB. The gate dielectric layer 110W may include a first gate dielectric layer 110WA formed on the wave-shaped first side wall 105WA and a second gate dielectric layer 110WB formed on the wave-shaped second side wall 105WB.

Three side wall facets among the side wall facets of the second node 104V may be covered by the wave-shaped gate electrode 120W.

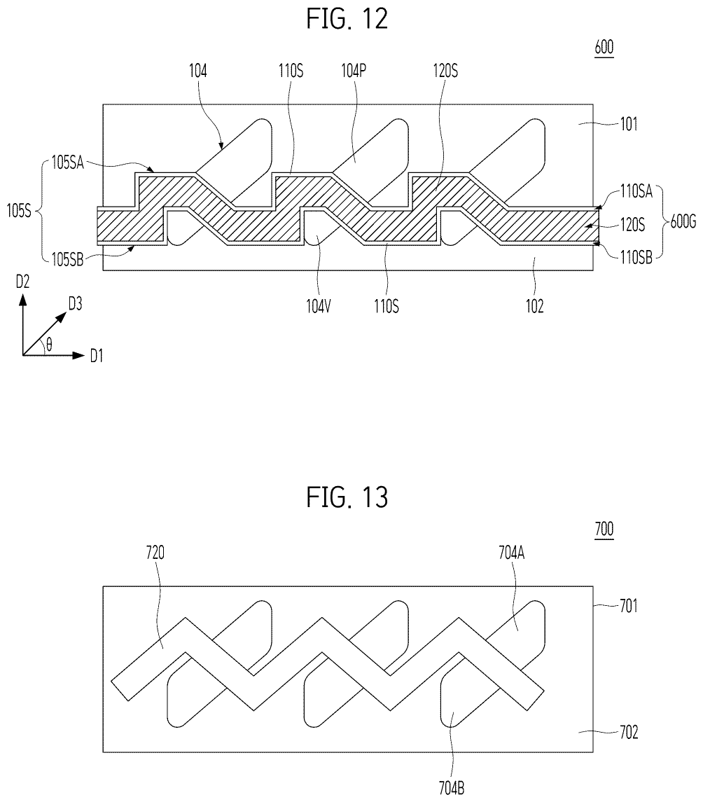

Referring to FIG. 12, the semiconductor device 600 may include a substrate 101, an isolation layer 102, active regions 104, and a buried gate structure 600G. The active regions 104 may include strips and may be arranged in the form of an array. The array of the active regions 104 may include a row array. The row array of active regions 104 may include the active regions 104 that are arranged in the first direction D1. The longitudinal direction of the active regions 104, i.e., the third direction D3, may be non-orthogonal to the first direction D1 and the second direction D2 to form an intersection angle (θ). The intersection angle (θ) between the first direction D1 and the third direction D3 of the active regions 104 may range from approximately 10° to 80°, but the concept and spirit of the present embodiment may not be limited thereto.

The buried gate structure 600G may be formed in the gate trench 105W. The buried gate structure 600G may include a gate dielectric layer 110S and a gate electrode 120S. The gate trench 105S and the gate electrode 120S may have a continuous wave shape, for example, they may have a continuous sawtooth wave shape. The gate trench 105S may include a sawtooth wave-shaped first side wall 105SA and a sawtooth wave-shaped second side wall 105SB. The gate dielectric layer 110S may include a first gate dielectric layer 110SA formed on the sawtooth wave-shaped first side wall 105SA and a second gate dielectric layer 110SB formed on the sawtooth wave-shaped second side wall 105SB.

Three side wall facets among the side wall facets of the second node 104V may be covered by the gate electrode 120S having a sawtooth wave shape.

Referring to FIGS. 8 to 12, data storage elements may be coupled to the first nodes 104P, and bit lines may be coupled to the second nodes 104V.

Referring to FIGS. 8 to 12, the active region 104 may not include a fin region disposed below the bottom surface of the trench 105, 105W and 105S. The active region 104 may have a non-saddle fin structure. The role of the saddle fin may be replaced by the second node 104V, and thus, the channel width may be increased by the second node 104V, and the electrical characteristics may be improved. Since the active region 104 has a non-saddle fin structure, the height of the passing gates PG may be decreased, as illustrated in FIG. 1C, which may decrease the effect of the row hammering.

FIG. 13 is a schematic plan view illustrating a semiconductor device according to a comparative example.

Referring to FIG. 13, a semiconductor device 700 may include a substrate 701, an isolation layer 702, an active region 704, and a gate electrode 720. The active region 704 may include a first node 704A and a second node 704B. The gate electrode 720 may have a triangle wave shape.

The gate electrode 720 of the comparative example may have an increased area facing the active region 704, which may increase the gate-induced drain leakage (GIDL). Further, the gate electrode 720 may have a weak passing gate effect due to the concentration of an electric field that is caused by the triangle wave shape, which may deteriorate the row hammering.

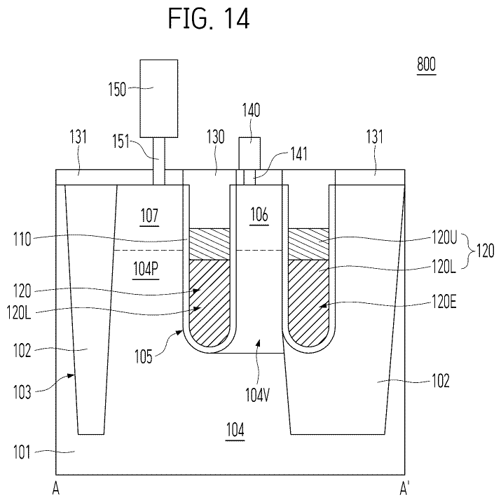

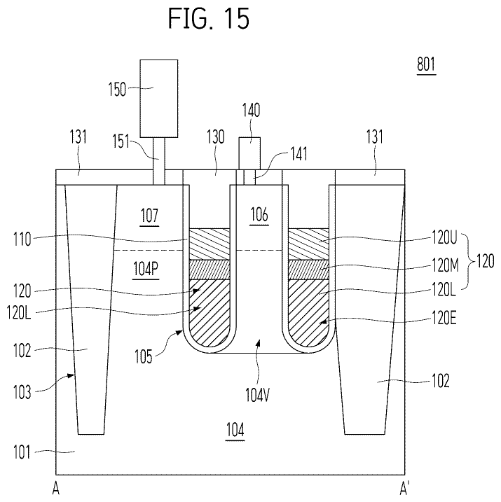

FIGS. 14 and 15 illustrate semiconductor devices in accordance with other embodiments of the present disclosure. FIGS. 14 and 15 may be similar to the semiconductor device 100 of FIGS. 1A to 1F. As to the detailed description on the constituent elements also appearing in FIGS. 1A to 1F, the description of FIGS. 1A to 1F may be referred to.

The semiconductor devices 800 and 801 may include a memory cell of the 1G1A structure.

Referring to FIG. 14, the buried gate electrode 120 of the semiconductor device 800 may have a dual work function structure. The buried gate electrode 120 may include a lower gate electrode 120L and an upper gate electrode 120U. The lower gate electrode 120L may be a high work function material, and the upper gate electrode 120U may be a low work function material. The lower gate electrode 120L may be a metal-based material, and the upper gate electrode 120U may be a semiconductor material. The lower gate electrode 120L may include titanium nitride, tungsten, or a stack thereof, and the upper gate electrode 120U may be doped polysilicon. Doped polysilicon may refer to polysilicon doped with an N-type dopant. According to another embodiment of the present disclosure, the lower gate electrode 120L may be a high-work function titanium nitride, and the upper gate electrode 120U may be a low-work function titanium nitride. The difference between the work function of the high-work function titanium nitride and the work function of the low-work function titanium nitride may be controlled according to the nitrogen content. Nitrogen-rich titanium nitride (TiN) having a higher nitrogen content than stoichiometric titanium nitride may have a high work function.

The upper gate electrode 120U may horizontally overlap with the first doped region 106 and the second doped region 107.

The gate-induced drain leakage (GIDL) may be further alleviated by the low-work function upper gate electrode 120U.

Referring to FIG. 15, the buried gate electrode 120 of the semiconductor device 801 may have a triple work function structure. The buried gate electrode 120 may include a lower gate electrode 120L, an upper gate electrode 120U, and a middle gate electrode 120M between the lower gate electrode 120L and the upper gate electrode 120U. The lower gate electrode 120L may be a high work function material, and the upper gate electrode 120U may be a low work function material, and the middle gate electrode 120M may be a middle work function material. The middle work function of the middle gate electrode 120M may be greater than the low work function of the upper gate electrode 120U and less than the high work function of the lower gate electrode 120L. The lower gate electrode 120L may be a metal-based material, and the upper gate electrode 120U may be a semiconductor material. The middle gate electrode 120M may include a metal-based material, a semiconductor material, or a combination thereof. The lower gate electrode 120L may include titanium nitride, tungsten, or a stack thereof, and the upper gate electrode 120U may include doped polysilicon. Doped polysilicon may refer to polysilicon that is doped with an N-type dopant. According to another embodiment of the present disclosure, the lower gate electrode 120L may be a high-work function titanium nitride, and the upper gate electrode 120U may be a low-work function titanium nitride. The difference between the work function of the high-work function titanium nitride and the work function of the low-work function titanium nitride may be controlled according to the nitrogen content. Nitrogen-rich titanium nitride (TiN) with a higher nitrogen content than a stoichiometric titanium nitride may have a high work function.

The upper gate electrode 120U may horizontally overlap with the first doped region 106 and the second doped region 107.

The gate-induced drain leakage (GIDL) may be further improved by the upper gate electrode 120U of the low work function.

According to an embodiment of the present disclosure, gate controllability may be secured by forming an active region of a vertical fin structure, and row hammering may be improved by decreasing the height of the passing gate.

According to an embodiment of the present disclosure, it is possible to simultaneously secure a low margin of a threshold voltage due to the buried gate structure and the vertical fin structure and improve the refresh/row hammering due to a decrease in the fin height.

While the embodiments of the present disclosure have been described with respect to specific embodiments, it will be apparent to those skilled in the art that various changes and modifications may be made without departing from the spirit and scope of the present disclosure as defined in the following claims. Furthermore, the embodiments may be combined to form additional embodiments.

What is claimed is:

1. A semiconductor device comprising:
an active region disposed in a substrate;
a first node and a second node defined in the active region; and
a buried electrode including:
a linear portion disposed between the first node and the second node to be through the active region; and
an extended portion protruding from the linear portion to partially cover side walls of the second node.

2. The semiconductor device of claim 1, wherein the second node includes a vertical fin structure.

3. The semiconductor device of claim 1, wherein the linear portion and the extended portion have an integrated structure.

4. The semiconductor device of claim 1,
wherein the side walls of the second node include at least four side wall facets, and
wherein the extended portion covers at least three side wall facets among the at least four side wall facets.

5. The semiconductor device of claim 1, further comprising:
a dielectric layer disposed between the linear portion and the first node, and between the extended portion and the second node.

6. The semiconductor device of claim 5, wherein the dielectric layer partially covers the side walls of the second node.

7. The semiconductor device of claim 1, further comprising:
a data storage element disposed over the substrate and coupled to the first node; and
a bit line disposed over the substrate and coupled to the second node.

8. The semiconductor device of claim 1, wherein each of the first node and the second node includes a polygon having at least four side wall facets.

9. The semiconductor device of claim 1, wherein one gate electrode is disposed in the active region.

10. The semiconductor device of claim 1, wherein the extended buried electrode protrudes from the linear buried electrode and has a symmetrical structure with the second node interposed therebetween.

11. The semiconductor device of claim 1, wherein the extended buried electrode includes
extended buried electrodes protruding from the linear buried electrode and having an asymmetrical structure with the second node interposed therebetween.

12. The semiconductor device of claim 1, wherein the buried electrode has a continuous wave shape, a square wave shape, or a sawtooth wave shape at a plan view.

13. A semiconductor device comprising:
a first active node including a plurality of first side wall facets;
a second active node including a plurality of second side wall facets, the first active node and the second active node being defined in a substrate;
a bit line disposed over the substrate and coupled to the first active node;
a data storage element disposed over the substrate and coupled to the second active node;
and
a gate electrode buried between the first active node and the second active node,
wherein the gate electrode includes:
a first segment facing one first side wall facet among the plurality of first side wall facets; and
second segments extending from the first segment and covering at least three second side wall facets among the plurality of second side wall facets.

14. The semiconductor device of claim 13, wherein each of the first active node and the second active node includes a polygon having at least four or more side wall facets.

15. The semiconductor device of claim 13, wherein the first active node and the second active node are included in one active region, and one gate electrode is disposed in the one active region.

16. The semiconductor device of claim 13, wherein the second active node includes a vertical fin structure.

17. The semiconductor device of claim 13, wherein:
the gate electrode includes a comb-shaped structure;
the first segment corresponds to a body of the comb-shaped structure; and
the second segments correspond to teeth of the comb-shaped structure.

18. The semiconductor device of claim 13, further comprising a gate dielectric layer disposed between the gate electrode and the first active node, and between the gate electrode and the second active node.

19. The semiconductor device of claim 13, further comprising an isolation layer disposed to be adjacent to each of the first active node and the second active node.

20. The semiconductor device of claim 19, wherein the second segments of the gate electrode extend into the isolation layer to cover the at least three second side wall facets among the plurality of second side wall facets.
